(19) United States
(12) Patent Application Publication
(10) Pub. No.: US 2006/0109615 A1
(43) Pub. Date: May 25, 2006

(54) Electronic apparatus including housing

(75) Inventors: Kazunori Kunimoto, Echizen-shi (JP); Takato Oda, Echizen-shi (JP)

Correspondence Address: REED SMITH LLP, 3110 Fairview Park Drive, Suite 1400, Falls Church, VA, 22042, US

(73) Assignee: Orion Electric Company Ltd.

(21) Appl. No.: 11/265,158

(22) Filed: Nov. 3, 2005

(30) Foreign Application Priority Data
Nov. 25, 2004 (JP) 2004-341131

(51) Int. Cl. H05K 5/00; H02G 3/08

(52) U.S. Cl. 361/679; 174/52.1

(57) ABSTRACT

The electronic apparatus such as a DVD player 1 configured so that the chassis 2 and the top plate 3 are substantially equal in width and so that each side surface 3B of the top plate 3 is overlaid on an outer surface of each side plate 2B of the chassis 2 is assumed as a standard type. For the electronic apparatus such as a DVD player 1 having the top plate 3 wider than the chassis 2, a recess 32 that partially surface-contacts with the outer surface of each side plate 2B of the chassis 2 is formed on each side surface 3B of the top plate 3 by deep drawing. It is thereby possible to make the chassis 2 common to the top plates 3 and the front panels 4 of different types.

### BACKGROUND OF THE INVENTION

1. Field of the Invention

The present invention relates to an electronic apparatus including a housing. More specifically, the present invention relates to an electronic apparatus including housing and capable of using a common chassis.

2. Description of the Related Art

Conventionally, a housing employed in a disk player, a hard disk recording and reproducing apparatus or the like is normally configured so that electronic components are assembled into a chassis, the chassis is covered with a top plate, and an open front of an assembly composed of the chassis and the top plate is covered with a front panel. Japanese Patent Application Laid-Open No. 2001-298276 discloses an electronic apparatus housing including a chassis constituted by a lower wall of the housing and a cover constituted by an upper wall of the housing, wherein the chassis and the cover are constituted by components equal in shape.

However, the electronic apparatus housing disclosed in Japanese Patent Application Laid-Open No. 2001-298276 has the following disadvantages. By making the chassis and the cover constituting the housing equal in shape and using components common to the chassis and the cover, the number of components is decreased. In case of housings different in sizes, however, it is necessary to form chassis and covers according to the different sizes, respectively. It is assumed that electronic apparatuses such as disk players are to be supplied to a plurality of manufactures. In this case, even if electronic components having a common specification and stored in the respective housings are substantially equal, it is natural that the housings including front panels differ in shape and size. Due to this, it is necessary to form various types of chassis and covers that constitute the housings according to specifications of the different manufactures, respectively. As a result, although the electronic components stored in the respective housings are substantially equal, it is necessary to manufacture dedicated housings independently of one another. This causes an increase in manufacturing cost, since common components cannot be utilized.

### SUMMARY OF THE INVENTION

The present invention has been achieved to solve the conventional disadvantages. It is an object of the present invention to provide an electronic apparatus including a housing capable of using a common chassis, into which various electronic components are assembled, when manufacturing housings different in external size.

According to a first aspect of the present invention, there is provided an electronic apparatus including a housing, wherein the housing includes: a chassis into which electronic components of various types are assembled; a top plate that covers the chassis; and a front panel that covers an open front of an assembly composed of the chassis and the top plate, the housing storing the electronic components, a plurality of top plates different in width and a plurality of front panels different in width are formed, and one of the plurality of top plates and one of the plurality of front panels are selectively attached to the chassis, thereby using the chassis to be common to the plurality of top plates and the plurality of front panels.

According to the first aspect of the present invention, a plurality of top plates different in width and a plurality of front panels different in width are formed, and one of the top plates and one of the front panels are selectively attached to the chassis into which electronic components of various types are assembled so as to use the chassis to be common to the plurality of top plates and the plurality of front panels. By so configuring, it is possible to use the common chassis even if the top plates and the front panels different in width are used.

According to a second aspect of the present invention, there is provided an electronic apparatus including a housing, wherein the chassis includes: a bottom plate onto which the electronic components are attached; a pair of left and right side plates bent from both side ends of the bottom plate, respectively; and a rear plate that is bent from a rear end of the bottom plate, and that constitutes a back surface of the housing, the top plate includes: an upper surface that covers the bottom plate; and a pair of left and right side surfaces provided to be perpendicular to both sides of the upper surface, respectively, and the housing configured so that the chassis and the top plate are substantially equal in width and so that each of the side surfaces of the top plate is overlaid on an outer surface of each of the side plates of the chassis is assumed as a standard type, and for the housing having the top plate wider than the chassis, a recess partially surface-contacting with the outer surface of the each side plate of the chassis is formed on the each side surface of the top plate.

According to the second aspect of the present invention, the housing configured so that the chassis and the top plate are substantially equal in width and so that each of the side surfaces of the top plate is overlaid on an outer surface of each of the side plates of the chassis is assumed as a standard type, and for the housing having the top plate wider than the chassis, a recess partially surface-contacting with the outer surface of the each side plate of the chassis is formed on the each side surface of the top plate. By so configuring, the each side surface of the top plate can partially surface-contact with the outer surface of each side plate of the chassis, and the top plate can be, therefore, attached to the chassis.

According to a third aspect of the present invention, there is provided an electronic apparatus including a housing, wherein the recess is formed by deep drawing and serves as a grip.

According to the third aspect of the present invention, by forming the recess by deep drawing, the recess can serve as a grip or grip means for carrying the electronic apparatus without increasing the number of components. In addition, by forming the recess on each side surface of the housing, the strength of the housing can be intensified.

According to a fourth aspect of the present invention, there is provided an electronic apparatus including a housing, wherein the housing includes: a chassis; a top plate; and a front panel, and stores electronic components of various types, the chassis including: a bottom plate onto which various electronic components are attached, a pair of left and right side plates bent from both side ends of the bottom plate, respectively, and a rear plate bent from a rear end of the bottom plate, the top plate including: a pair of left and right side surfaces provided to be perpendicular to left and right sides, respectively, and covering the chassis, and the front panel covering an open front of an assembly composed of the chassis and the top plate, the top plate is formed wider than the chassis, a gap is formed between an outer surface of each of the side plates of the chassis and each of the side surfaces of the top plate, a recess is formed on the each side surface of the top plate, the recess partially surface-contacting with an outer surface of the each side plate of the chassis, and a pair of grips are formed on both sides of the housing, respectively, each of the grips being formed out of the recess.

According to the fourth aspect of the present invention, by forming the recess serving as a grip on each side surface of the housing, it is unnecessary to additionally attach grip means to the housing, and forming machining can be facilitated. In addition, by forming the recess on each side surface of the housing, the strength of the housing can be intensified.

According to the first aspect of the present invention, there is provided an electronic apparatus including a housing, wherein the housing includes: a chassis into which electronic components ofvarious types are assembled; a top plate that covers the chassis; and a front panel that covers an open front of an assembly composed of the chassis and the top plate, the housing storing the electronic components, a plurality of top plates different in width and a plurality of front panels different in width are formed, and one of the plurality of top plates and one of the plurality of front panel are selectively attached to the chassis, thereby using the chassis to be common to the plurality of top plates and the plurality of front panels. Thus, if a plurality of top plates and a plurality of front panels are formed whena pluralityof electronic apparatuses different in width is manufactured, then it is unnecessary to form a plurality of chassis according to widths of the top plates, respectively, and the common chassis can be used. It is, therefore, possible to save manufacturing cost as compared with an instance in which a plurality of chassis is formed.

According to the second aspect of the present invention, there is provided an electronic apparatus including a housing, wherein the chassis includes: a bottom plate onto which the electronic components are attached; a pair of left and right side plates bent from both side ends of the bottom plate, respectively; and a rear plate that is bent from a rear end of the bottom plate, and that constitutes a back surface of the housing, the top plate includes: an upper surface that covers the bottom plate; and a pair of left and right side surfaces provided to be perpendicular to both sides of the upper surface, respectively, and the housing configured so that the chassis and the top plate are substantially equal in width and so that each of the side surfaces of the top plate is overlaid on an outer surface of each of the side plates of the chassis is assumed as a standard type, and for the housing having the top plate wider than the chassis, a recess partially surface-contacting with the outer surface of the each side plate of the chassis is formed on the each side surface of the top plate. Thus, even the top plate substantially equal in width to the chassis can be attached to the chassis. In addition, even in case of the housing having the top plate wider than the chassis, the recess partially surface-contacting with the outer surface of the each side plate of the chassis is formed on the each side surface of the top plate, whereby the recess can partially surface-contact with the outer surface of the each side plate of the chassis, and the top plate can be, therefore, attached to the chassis.

According to the electronic apparatus according to the third aspect of the present invention, the recess is formed by deep drawing and the recess is used as a grip. It is thereby possibletoeasilyprovidegripmeansforcarryingtheelectronic apparatus without increasing the number of components. Since the grip is formed on each side surface of the top plate by subjecting each side surface thereof to deepdrawing, an external view of the electronic apparatus is not injured by attachment of excessive components to the electronic apparatus. Further, since the recess is formed by the deep drawing, the recess can advantageously reinforce the strength of each side surface of the top plate.

According to the fourth aspect of the present invention, there is provided an electronic apparatus including a housing, wherein the housing includes: a chassis; a top plate; and a front panel, and stores electronic components of various types, the chassis including: a bottom plate onto which various electronic components are attached, a pair of left and right side plates bent from both side ends of the bottom plate, respectively, and a rear plate bent from a rear end of the bottom plate, the top plate including: a pair of left and right side surfaces provided to be perpendicular to left and right sides, respectively, and covering the chassis, and the front panel covering an open front of an assembly composed of the chassis and the top plate, the top plate is formed wider than the chassis, a gap is formed between an outer surface of each of the side plates of the chassis and each of the side surfaces of the top plate, a recess is formed on the each side surface of the top plate, the recess partially surface-contacting with an outer surface of the each side plate of the chassis, and a pair of grips are formed on both sides of the housing, respectively, each of the grips being formed out of the recess. Thus, by providing the recess formed on each side surface of the housing, a grip can be formed on the housing without additionally attaching a dedicated component to serve as the grip to the housing, and forming machining can be facilitated. In addition, the recess formedoneach side surface of the housing can intensify the strength of the housing.

### BRIEF DESCRIPTION OF THE DRAWINGS

FIG. 1 is an exploded perspective view showing constituent components of an electronic apparatus including a housing according to an embodiment of the present invention;

FIG. 2 is a cross-sectional view showing a chassis and a top plate, equal in width, ofthe electronic apparatus according to the embodiment of the present invention;

FIG. 3 is a perspective view showing an electronic apparatus in which a top plate is wider than a chassis according to the embodiment of the present invention;

FIG. 4 is a cross-sectional view taken along a line A-A of FIG. 3, which view depicts the electronic apparatus in which the top plate is wider than the chassis according to the embodiment of the present invention;

FIG. 5 is a cross-sectional view taken along a line B-B of FIG. 3, which view depicts the electronic apparatus in which the top plate is wider than the chass is according to the embodiment of the present invention; and

FIG. 6 is a perspective view showing a state in which a user puts his or her hands on respective grips formed on both side surfaces of the electronic apparatus in which the top plate is wider than the chassis so as to lift the electronic apparatus according to the embodiment of the present invention.

### DESCRIPTION OF THE PREFERRED EMBODIMENT

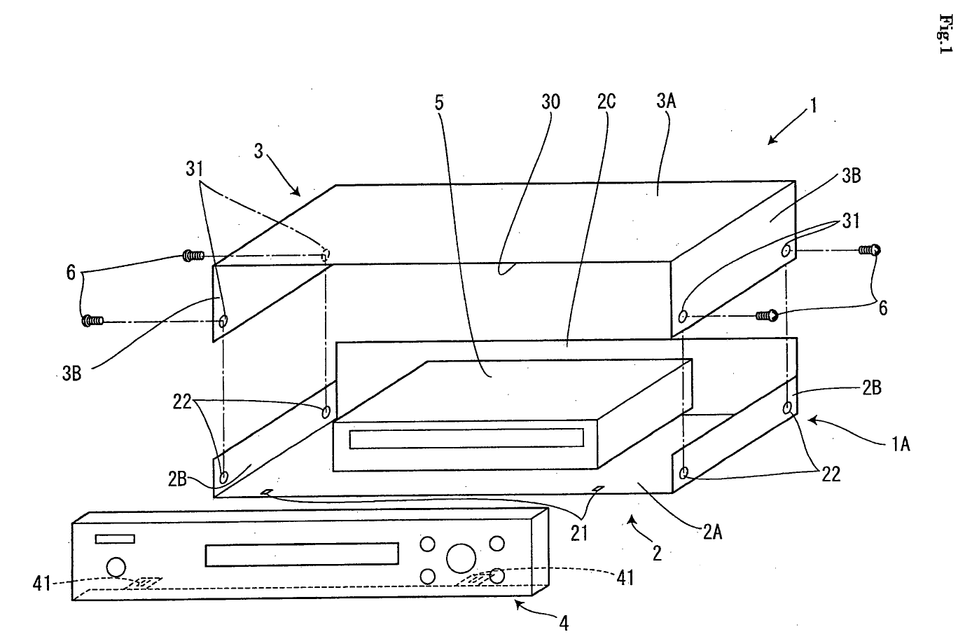

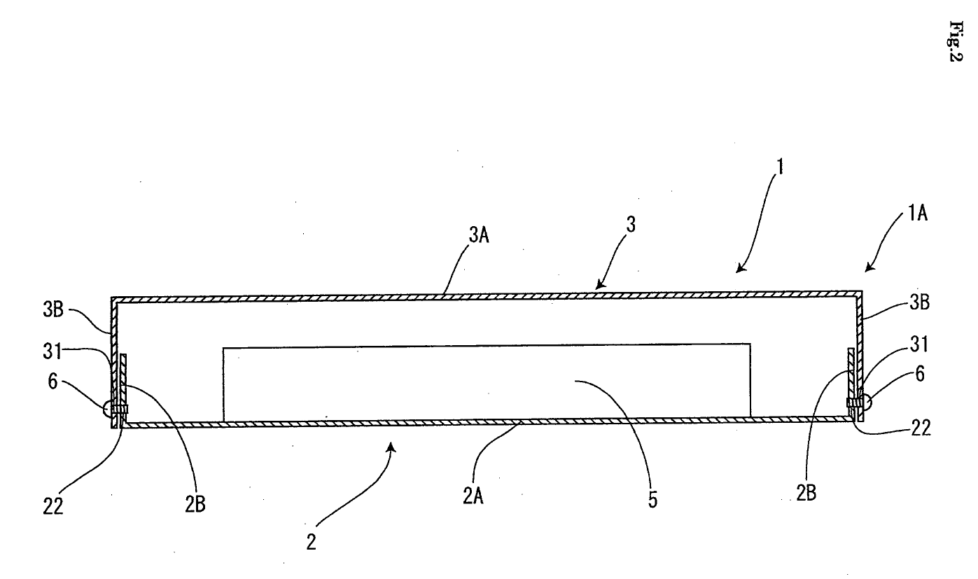

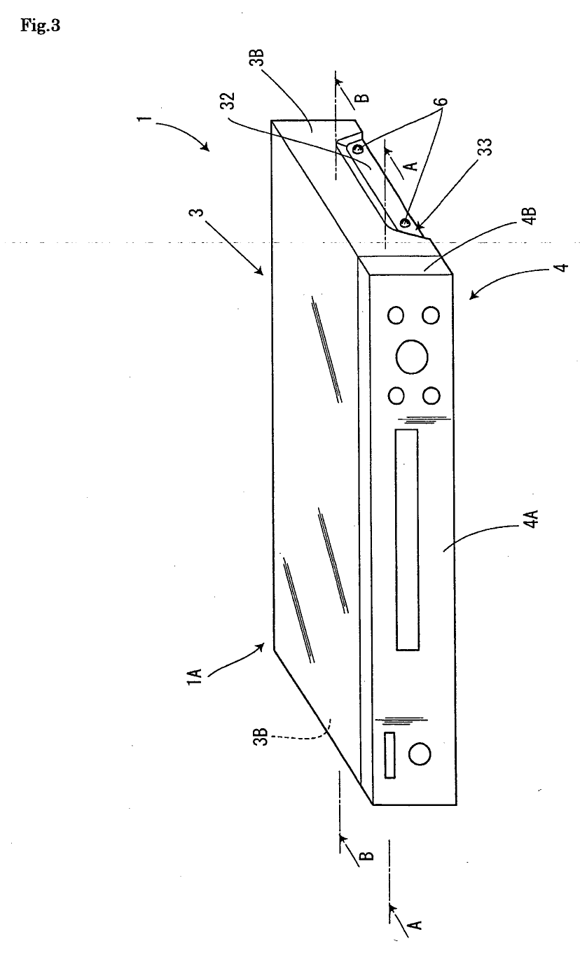

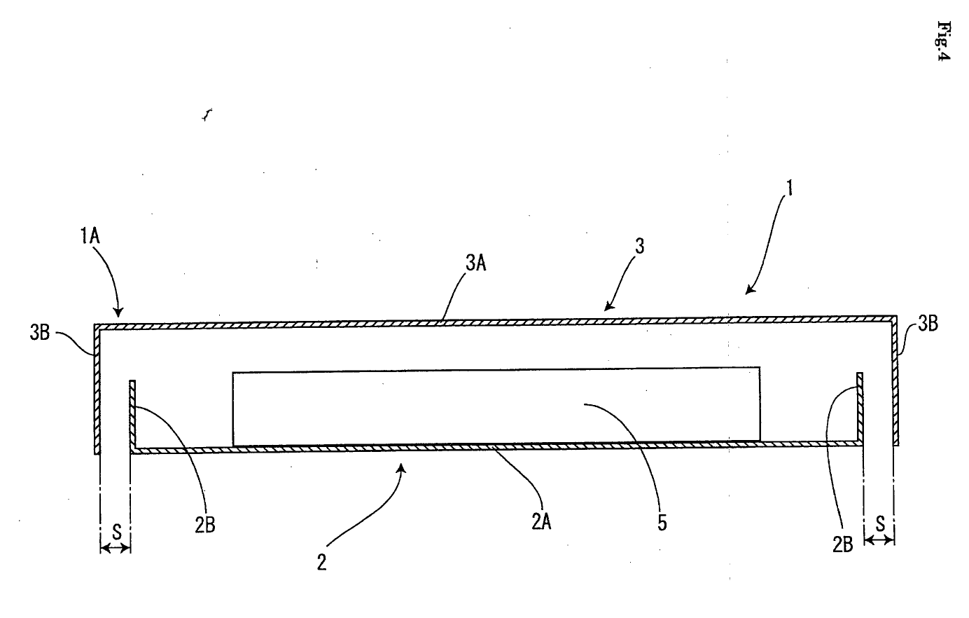

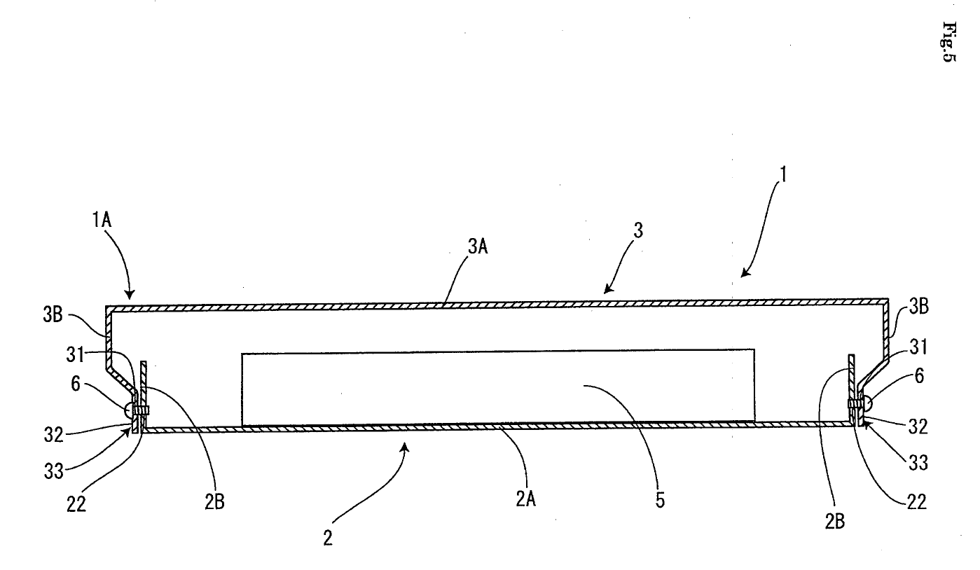

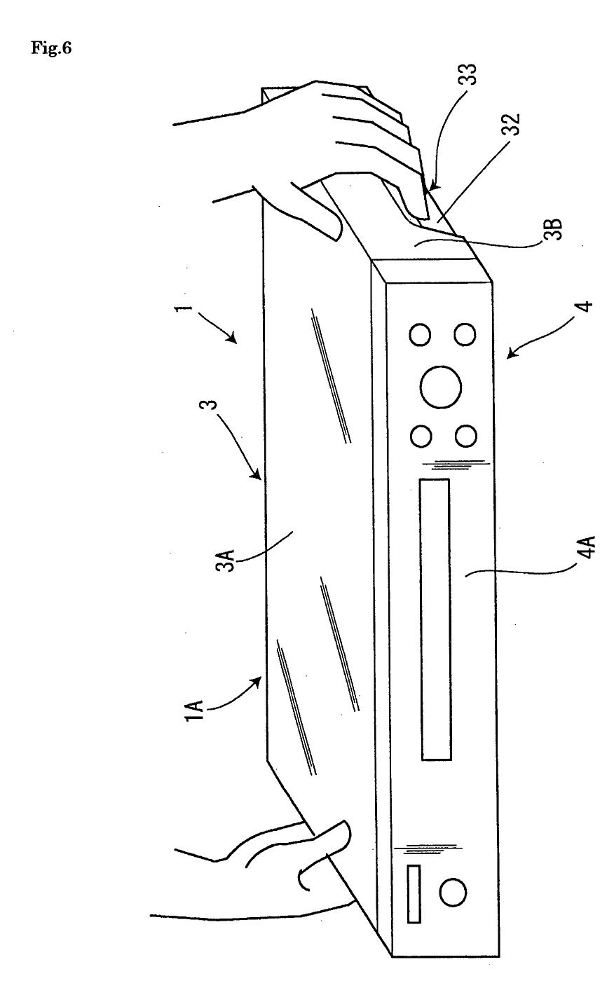

An electronic apparatus including a housing according to an embodiment of the present invention will be described hereinafterwith reference tothe drawings. FIG. 1 is an exploded perspective view that depicts constituent components of the electronic apparatus including the housing. FIG. 2 is a cross-sectional view that depicts a chassis and a top plate, equal in width, of the electronic apparatus. FIG. 3 is a perspective view that depicts an electronic apparatus in which a top plate is wider than a chassis. FIG. 4 is a cross-sectional view taken along a line A-A of FIG. 3, which view depicts the electronic apparatus in which the top plate is wider than the chassis. FIG. 5 is a cross-sectional view taken along a line B-B of FIG. 3, which view depicts the electronic apparatus in which the top plate is wider than the chassis. FIG. 6 is a perspective view that depicts a state in which a user puts his or her hands on respective grips formed on both side surfaces of the electronic apparatus in which the top plate is wider than the chassis so as to lift the electronic apparatus. In this embodiment, an instance in which a DVD player 1 is employed as the electronic apparatus will be described. As shown in FIGS. 1 to 6, the DVD player 1 includes a housing lA that stores various electronic components 5 such as a disk device and a circuit board driving the disk device and that is configured to include a chassis 2, a top plate 3, and a front panel 4.

The chassis 2 includes a bottom plate 2A onto which the various electronic components 5 are attached, a pair of left and right side plates 2B bent from both side ends of the bottom plate 2A, respectively, and a rear plate 2C bent from a rear end of the bottom plate 2A and constituting a back surface of the housing 1A. The top plate 3 includes an upper surface 3A bent to have a U-shaped cross section and covering the bottom plate 2A, and a pair of left and right side surfaces 3B provided to be perpendicular to both sides of the upper surface 3A, respectively. The front panel 4 includes a front surface panel 4Aandaframeportion4Bformedintegrallywiththis front surface panel 4A from peripheral edges to a rear portion of the front surface panel 4A.

An attachment structure of the housing 1A will be described. Screw holes 22 are formed in each side plate 2B of the chassis 2, and through holes 31 for screws 6 are formed in each side surface 3B of the top plate 3 at positions corresponding to the respective screw holes 22. Engagement hooks 41 are formed on abottomof the frame portion 4B of the front panel 4. Engagement holes 21 engaged with the respective engagement hooks 41 are formed in the bottom plate 2A of the chassis 2. As shown in FIG. 2, the chassis 2 into which the various electronic components 5 are assembled is covered with the top plate 3, the side surfaces 3B of the top plate 3 are overlaid on outer surfaces of the respective side plates 2B of the chassis 2, and the screws 6 are screwed into the respective screw holes 22 of the chassis 2 from the through holes 31 of the top plate 3. The chassis 2 and the top plate 3 are thereby fixed to each other. Thereafter, the frame portion 4B of the front panel 4 is fitted into a front surface of the chassis 2 and that of the top plate 3, thereby covering an open front 30 of an assembly composed of the chassis 2 and the top plate 3 with the front panel 4. In addition, the engagement hooks 41 of the front panel 4 are engaged with the respective engagement holes 21 of the chassis 2. The front panel 4 is thus fixedly attached to the chassis 2 and the top plate 3.

As shown in FIG. 2, if the chassis 2 into which the various electronic components 5 are assembled is substantially equal in width to the front panel 4 attached to the chassis 2, it is natural that the top plate 3 attached to the chassis 2 is substantially equal in width to the chassis 2. The housing 1A of this type is assumed as a standard type. If the electronic apparatus such as the DVD player 1 is supplied to another manufacturer different in, for example, a design of the front panel 4, then the front panel 4 may possibly differ in width and size from that in the standard type housing 1A and the front panel 4 may possibly be wider than the chassis 2. Naturally, in this case, as shown in FIGS. 4 and 5, a gap S is generated between each side plate 2B of the chassis 2 and each side surface 3B of the top plate 3 in a A-A cross section of the electronic apparatus such as the DVD player 1 having the wider top plate 3. If the front panel 4 and the top plate 3 are thus wider than the chassis 2, then a recess 32 is formed by subjecting each side surface 3B of the top plate 3 to deep drawing, and a bottom of the recess 32 is brought into surface-contact with the corresponding side plate 2B of the chassis 2, as shown in FIGS. 3 and 5. Namely, even if the front panel 4 and the top plate 3 are wider than the chassis 2, the front panel 4 and the top plate 3 can be attached to the narrower chassis 2 by forming the recess 32 on each side surface 3B of the top plate 3. The housing 1A configured so that the front panel 4 and the top plate 3 are substantially equal in width to the chassis 2 into which the various electronic components 5 are assembled is assumed as the standard type, as stated. As for the housing 1A having the front panel 4 and the top plate 3 wider than the chassis 2, a plurality of types of top plates 3 on which the recesses 32 are formed according to differences in width, respectively, are prepared. One of the top plates 3 is selectively attached to the chassis 2. It is there by possible to use the common chassis 2, into which the various electronic components 5 are assembled, to the different types of housings 1A. By thus using the common chassis 2 into which the various electronic components 5 are assembled, production efficiency can be improved and manufacturing cost can be reduced, accordingly. In addition, the recesses 32 formed on the top plate 3 can serve as grips 33 as shown in FIG. 6. Therefore, it is unnecessary to additionally provide grip means for carrying the electronic apparatus such as the DVD player 1 in this embodiment, without increasing the number of components. Besides, since the recesses 32 also serving as the grips 33 are formed by subjecting the both side surfaces 3B of the top plate 3 to the deep drawing, an external view of the electronic apparatus such as the DVD player 1 is not injured by attachment of excessive components to the electronic apparatus such as the DVD player 1. Further, since the recesses 32 are formed by the deep drawing, the recesses 32 can advantageously reinforce strengths of the respective side surfaces 3B of the top plate 3.

The embodiment of the present invention has been described so far in detail. However, the present invention is not limited to the embodiment but various modifications can be made to the present invention within the scope of the present invention. For example, in the embodiment, only one recess 32 formed by the drawing is provided on each side surface 3B of the top plate 3. Alternatively, a plurality of recesses 32 may be provided on each side surface 3B of the top plate 3. In addition, a shape and the like of each recess 32 is not limited to those described in the embodiment but may be appropriately selected.

What is claimed is:

1. An electronic apparatus including a housing, wherein
the housing includes: a chassis into which electronic components ofvarious types are assembled; atopplate that covers the chassis; and a front panel that covers an open front of an assembly composed of the chassis and the top plate, the housing storing the electronic components,
a plurality of top plates different in width and a plurality of front panels different in width are formed, and
one of the plurality of top plates and one of the plurality of front panels are selectively attached to the chassis, thereby using the chassis to be common to the plurality of top plates and the plurality of front panels.

2. The electronic apparatus including the housing according to claim 1, wherein
the chassis includes: a bottom plate onto which the electronic components are attached; a pair of left and right side plates bent from both side ends of the bottom plate, respectively; and a rear plate that is bent from a rear end of the bottom plate, and that constitutes a back surface of the housing,
the top plate includes: an upper surface that covers the bottomplate; anda pair of left and right side surfaces provided to be perpendicular to both sides of the upper surface, respectively, and
the housing configured so that the chassis and the top plate are substantially equal in width and so that each of the side surfaces of the top plate is overlaid on an outer surface of each of the side plates of the chassis is assumed as a standard type, and for the housing having the top plate wider than the chassis, a recess partially surface-contacting with the outer surface of the each side plate of the chassis is formed on the each side surface of the top plate.

3. The electronic apparatus including the housing according to claim 2, wherein
the recess is formed by deep drawing and serves as a grip.

4. An electronic apparatus including a housing, wherein
the housing includes: a chassis; a top plate; and a front panel, and stores electronic components of various types, the chassis including: a bottom plate onto which various electronic components are attached, a pair of left and right side plates bent from both side ends of the bottom plate, respectively, and a rear plate bent from a rear end of the bottom plate, the top plate including: a pair of left and right side surfaces provided to be perpendicular to left and right sides, respectively, and covering the chassis, and the front panel covering an open front of an assembly composed of the chassis and the top plate,
the top plate is formed wider than the chassis,
a gap is formed between an outer surface of each of the side plates of the chassis and each of the side surfaces of the top plate,
a recess is formed on the each side surface of the top plate, the recess partially surface-contacting with an outer surface of the each side plate of the chassis, and
a pair of grips are formed on both sides of the housing, respectively, each of the grips being formed out of the recess.
